(19) United States
(12) Patent Application Publication
(10) Pub. No.: US 2008/0087642 A1
(43) Pub. Date: Apr. 17, 2008

(54) Method for removing surface deposits in the interior of a chemical vapor deposition reactor

(76) Inventors: Herbert H. Sawin, Chestnut Hill, MA (US); Bo Bai, Cambridge, MA (US); Ju Jin An, Cambridge, MA (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(21) Appl. No.: 11/903,849

(22) Filed: Sep. 25, 2007

Related U.S. Application Data
(60) Provisional application No. 60/846,992, filed on Sep. 25, 2006.

(51) Int. Cl. C23C 16/00

(52) U.S. Cl. 216/67; 106/287.28; 118/723 R

(57) ABSTRACT

Disclosed is a deposition apparatus assembly comprising a deposition chamber, a remote chamber outside the deposition chamber for producing a reactive species from a precursor gas mixture, an activation source adapted to deliver energy into said remote chamber, a conduit for flowing the reactive species from said remote chamber to said deposition chamber and a flow restricting device interposed between said conduit and said remote chamber wherein said flow restricting device is cooled by an external source.

### CROSS REFERENCE(S) TO RELATED APPLICATION(S)

This application claims the benefit of priority of U.S. Provisional Application 60/846,992, filed Sep. 25, 2006.

### BACKGROUND INFORMATION

1. Field of the Disclosure

This disclosure relates in general to methods for removing surface deposits and an apparatus therefor.

2. Description of the Related Art

One of the problems facing the operators of chemical vapor deposition reactors is the need to regularly clean the chamber to remove deposits from the chamber walls and platens. This cleaning process reduces the productive capacity of the chamber since the chamber is out of active service during a cleaning cycle. The cleaning process may include, for example, the evacuation of reactant gases and their replacement with an activated cleaning gas followed by a flushing step to remove the cleaning gas from the chamber using an inert carrier gas. The cleaning gases typically work by etching the contaminant build-ups from the interior surfaces, thus the etching rate of the cleaning gas is an important parameter in the utility and commercial use of the gases.

Present cleaning gases are believed to be limited in their effectiveness due to low etch rates. In order to partially obviate this limitation, current gases need to be run at an inefficient flow rate, e.g. at a high flow rate, and thus greatly contribute to the overall operating cost of the CVD reactor. In turn this increases the production cost of CVD wafer products. Further attempts at increasing the pressure of the gases to increase the etch rates have instead resulted in lower etch rates. This is most likely due to the loss of gas phase species due to increased recombination at the increased pressures. Thus, there is a need in the art to reduce the operating costs of a CVD reactor with an effective cleaning gas capable of lowering the overall operating cost of the CVD chamber.

### SUMMARY

Disclosed is a deposition apparatus assembly comprising a deposition chamber, a remote chamber outside the deposition chamber for producing a reactive species from a precursor gas mixture, an activation source adapted to deliver energy into said remote chamber, a conduit for flowing the reactive species from said remote chamber to said deposition chamber and a flow restricting device interposed between said conduit and said remote chamber wherein said flow restricting device is cooled by an external source.

Also disclosed is an activated gas mixture comprising from about 50% to about 74% fluorine atoms, from about 6% to about 20% nitrogen atoms, from about 10% to about 20% oxygen atoms, and from about 10% to about 20% carbon atoms.

Also disclosed is a process for etching and removing surface deposits on the interior surfaces of a CVD apparatus, comprising activating in a remote chamber a gas mixture comprising an oxygen source, nitrogen trifluoride, a fluorocarbon, and nitrogen, using a power of at least 12 kW, allowing said activated gas mixture to flow through a water-cooled flow restricting device, a conduit and into a process chamber, and thereafter contacting said activated gas mixture with the surface deposits and thereby removing at least some of the said deposits.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes as illustration of a water cooling device for one embodiment of a flow restricting device in top and side views.

FIG. 2 illustrates an orifice as one embodiment of a flow restricting device top and side views.

FIG. 3 illustrates one embodiment of a water-cooled orifice assembly top and side views

FIG. 4 illustrates one embodiment of a deposition apparatus assembly.

FIG. 5 is a plot of silicon dioxide etching for various compositions as a function of plasma source pressure.

FIG. 6 is a plot of silicon dioxide etching for various compositions as a function of plasma source pressure.

FIG. 7 is a plot of silicon dioxide etching for various compositions as a function of plasma source pressure with a flow restricting device.

FIG. 8 is a plot of silicon dioxide etching for various compositions as a function of plasma source pressure without a flow restricting device.

FIG. 9 is a plot of silicon dioxide etching for various compositions as a function of plasma source pressure.

FIG. 10 is a plot of silicon dioxide etching for various compositions as a function of plasma source pressure.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims.

Definitions and Clarification of Terms

Before addressing details of embodiments described below, some terms are defined or clarified.

As used herein, a deposition chamber is a process chamber that is used in fabricating electronic devices. Such a process chamber could be a chemical vapor deposition (CVD) chamber or a plasma enhanced chemical vapor deposition (PECVD) chamber. As used herein, the term process chamber also refers to a deposition chamber.

As used herein, a remote chamber is the chamber other than the cleaning or process chamber, wherein the plasma may be generated.

As used herein, an activation source refers to any energy input means allowing for the achievement of dissociation of a large fraction of the feed gas or feed gas mixture, such as: radio frequency (RF) energy, direct current (DC) energy, laser illumination, and microwave energy.

As used herein, a flow restricting device is any orifice, restriction or valve which restricts the flow of the reactive species of the activated gas mixture from the remote chamber into the conduit and deposition chamber.

As used herein, reactive species refers to the dissociated atoms formed from dissociation of the precursor gas mixture. The reactive species formed in the remote chamber is also commonly referred to as an activated gas mixture, or as a plasma.

As used herein, an external cooling source is any means for removing heat from the flow restricting device, such as a water cooling reservoir with a circulating water pump.

Surface deposits as referred to herein comprise those materials commonly deposited by chemical vapor deposition (CVD), plasma-enhanced chemical vapor deposition (PECVD) or similar processes. Such materials include silicon-containing deposits, and nitrogen-containing deposits. Such deposits include, without limitation, silicon dioxide, silicon nitride, silicon oxynitride, silicon carbonitride (SiCN), silicon boronitride (SiBN), and metal nitrides, such as tungsten nitride, titanium nitride or tantalum nitride. In one embodiment of the invention, the surface deposit is silicon dioxide.

In one embodiment of the invention, surface deposits are removed from the interior of a deposition chamber that is used in fabricating electronic devices. Such a deposition chamber could be a CVD chamber or a PECVD chamber. Other embodiments of the invention include, but are not limited to, removing surface deposits from metals, the cleaning of plasma etching chambers and removal of Si-containing thin films from a wafer. In one embodiment, the deposition apparatus assembly comprises a deposition chamber, a remote chamber outside the deposition chamber for producing a reactive species from a precursor gas mixture, an activation source adapted to deliver energy into said remote chamber, a conduit for flowing the reactive species from said remote chamber to said deposition chamber and a flow restricting device interposed between said conduit and said remote chamber wherein said flow restricting device is cooled by an external source.

### DETAILED DESCRIPTION OF THE DRAWINGS

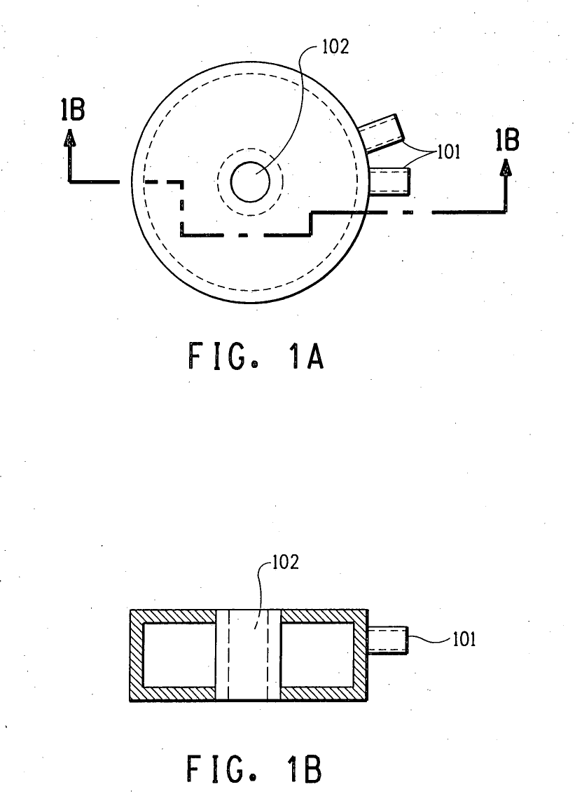

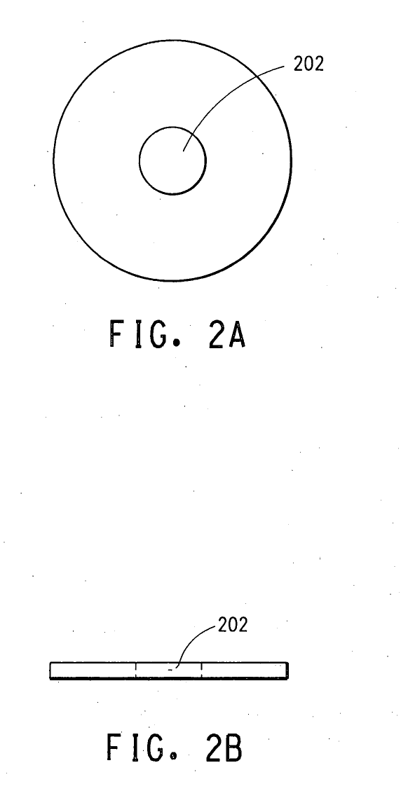

In one embodiment, the flow restricting device is an orifice which is cooled by circulating cooling water through a cooling jacket. One such embodiment is illustrated in FIGS. 1 and 2. FIG. 1 illustrates top and side views of one such embodiment having an inlet and outlet connector, 101, for the cooling water, to be connected to an external cooling water supply system. The cooling water jacket has an orifice, 102, axially through the jacket to allow flow of the activated gas mixture. FIG. 2 illustrates top and side views of one embodiment of the flow restricting device. In this embodiment, the flow restricting device comprises an orifice, 202, having a diameter of from about 0.25 inches to about 0.45 inches located centrally within the flow restricting device, and coaxially with the orifice in the cooling water jacket of FIG. 1.

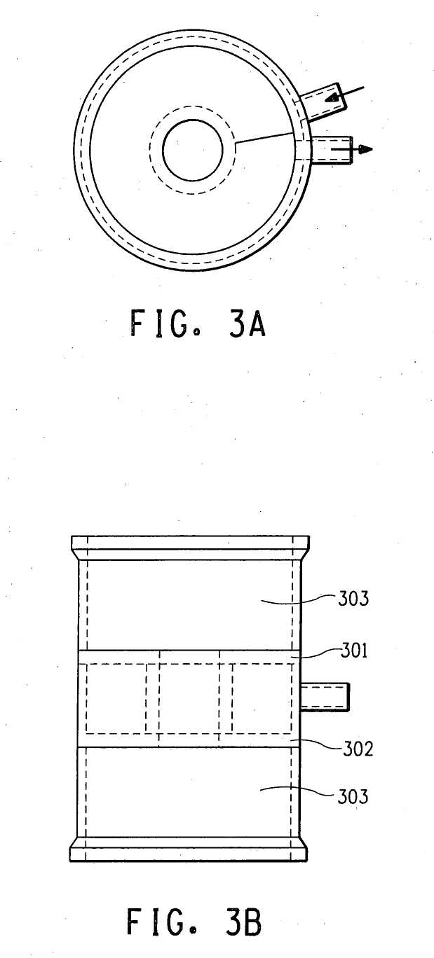

FIG. 3 illustrates one embodiment of a flow restricting device assembly. In this embodiment, the orifice device, 301, is connected to the cooling water jacket device, 302. The external faces of the device are connected to half nipples flanges, 303, which can be used to attach the flow restricting device to the remote chamber and to the conduit for flowing the reactive species to the deposition chamber.

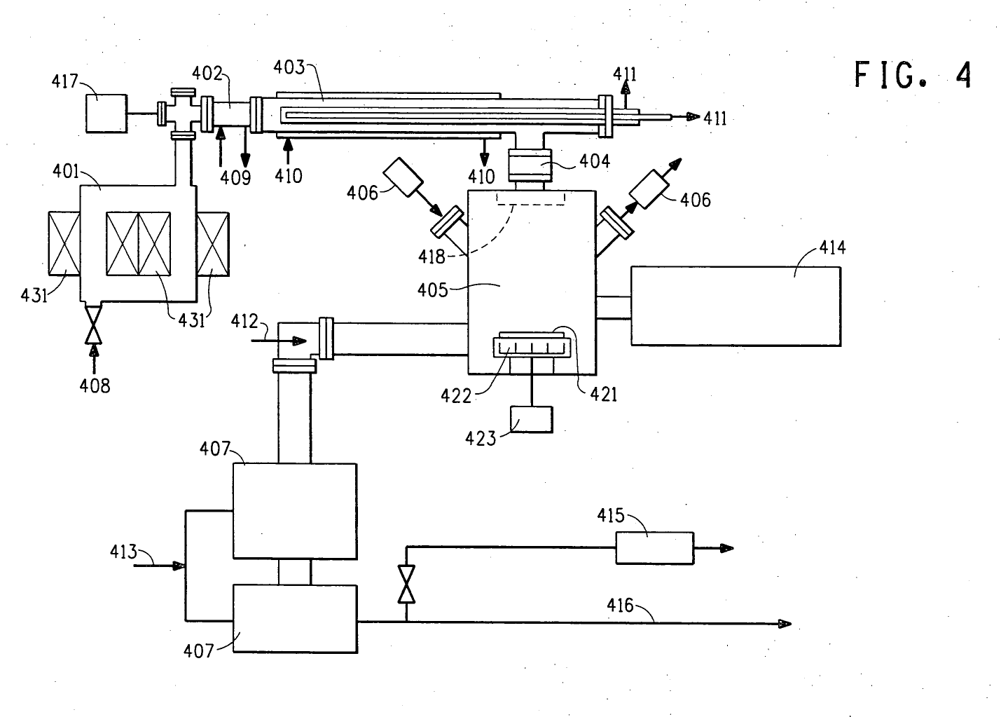

FIG. 4 illustrates one embodiment of a deposition apparatus assembly, comprising a remote chamber, 401, having a plasma source, a water cooled orifice as a flow restricting device, 402, a transfer tube, 403, for flowing the reactive species to the deposition chamber, a butterfly valve, 404, to optionally control flow in some experiments, a cleaning chamber, 405, as a deposition chamber, an interferometery system, 406, to perform measurements of etch rates, and a vacuum pump system, 407. Vacuum pump system, 407 also comprises a nitrogen purge inlet line, 413. A precursor gas mixture is fed into the plasma source through precursor gas inlet line, 408. The flow restricting device, 402, is cooled by water circulated through inlet and exit lines 409. The transfer tube, 403, is cooled with an external cooling jacket fed through inlet and exit lines, 410, and an internal cooling insert fed through inlet and exit lines, 411.

An activated gas mixture passes through butterfly valve, 404, and then through showerhead, 418, into the cleaning chamber, 405. Etching rates are measured using the interferometry system, 406, which comprises a He—Ne laser input to the chamber, and a photometer. Sample wafers, 421, for the etch rate experiments are mounted on wafer holder, 422, in the cleaning chamber. The temperature of the holder and the wafer is controller by temperature controller 423.

Pressure in the cleaning chamber, 405, is controlled using throttle valve, 412, on the exhaust line from the cleaning chamber. Vacuum pumps, 407, evacuate the system, and are fed with nitrogen purge gas through purge line, 413, both to dilute the products to a proper concentration for FT-IR measurement using the FT-IR system, 415, and to reduce the hang-up of products in the pump. Exhaust from both the pumps, 407, and FT-IR system, 415 flows out through exhaust line, 416. Pressure of the reactive gas exiting the remote chamber, prior to the flow restricting device, 409, is measured with a capacitance manometer, 417. The composition of gaseous species in the cleaning chamber can be monitored using the mass spectrometer, 414, connected to the cleaning chamber.

In one embodiment, the process of the present invention involves an activating step wherein a precursor gas mixture will be activated in the remote chamber. For the purposes of this application, activation means that at least an effective amount of the gas molecules have been substantially decomposed into their atomic species, e.g. a CF₄ gas would be activated to substantially decompose and form an activated gas (also known in the art as a plasma) comprising carbon and fluorine atoms. Activation may be accomplished by any energy input means allowing for the achievement of dissociation of a large fraction of the feed gas, such as: radio frequency (RF) energy, direct current (DC) energy, laser illumination, and microwave energy. One embodiment of this invention is using transformer coupled inductively coupled lower frequency RF power sources in which the plasma has a torroidal configuration and acts as the secondary of the transformer. The use of lower frequency RF power allows the use of magnetic cores that enhance the inductive coupling with respect to capacitive coupling; thereby allowing the more efficient transfer of energy to the plasma without excessive ion bombardment which limits the lifetime of the remote plasma source chamber interior. Typical RF power used in this invention has a frequency lower than 1000 kHz. In another embodiment of this invention the power source is a remote microwave, inductively, or capacitively coupled plasma source. In yet another embodiment of the invention, the gas is activated using glow discharge.

Activation of the precursor gas mixture uses sufficient power for a sufficient time to form an activated gas mixture. In one embodiment of the invention the activated gas mixture is activated with a power of at least 12 kW.

In one embodiment, the activated gas may be formed in a separate, remote chamber that is outside of the deposition chamber, but in close proximity to the deposition chamber. In this embodiment, remote chamber refers to the chamber other than the cleaning or deposition chamber, wherein the plasma may be generated, and deposition chamber refers to the chamber wherein the surface deposits are located. The remote chamber is connected to the deposition chamber through the flow restricting device, by any means allowing for transfer of the activated gas from the remote chamber to the process chamber. For example, the means for allowing transfer of the activated gas may comprise a short connecting tube connected to the flow restricting device, and a showerhead of the CVD/PECVD process chamber. In another embodiment, the means for allowing transfer of the activated gas may comprise a direct conduit from the flow restricting device attached to the remote plasma source chamber, to the deposition chamber. The remote chamber and means for connecting the remote chamber with the deposition chamber are constructed of materials known in this field to be capable of containing activated gas mixtures. For instance, aluminum and anodized aluminum are commonly used for the chamber components. Sometimes Al₂O₃ is coated on the interior surface to reduce the surface recombination. In other embodiments of the invention, the activated gas mixture may be formed directly in the process chamber.

The precursor gas mixture (that is to be activated to form the activated gas mixture) comprises an oxygen source, nitrogen trifluoride, a fluorocarbon, and molecular nitrogen. In one embodiment, an oxygen source is molecular oxygen. A fluorocarbon is herein referred to as a compound containing C and F, and optionally O and H. In one embodiment of the invention, a fluorocarbon is a perfluorocarbon or a mixture of one or more perfluorocarbons. A perfluorocarbon compound as referred to in this invention is a compound consisting of C, F and optionally oxygen. Such perfluorocarbon compounds include, but are not limited to tetrafluoromethane, hexafluoroethane, octafluoropropane, hexafluororcyclopropane, decafluorobutane, hexafluoropropene, octafluorocyclobutane and octafluorotetrahydrofuran. Without wishing to be bound by any particular theory, applicant believes that the fluorocarbon of the gas mixture serves as a source of carbon atoms in the activated gas mixture.

In one embodiment, the activated gas mixture comprises from about 50% to about 74% fluorine atoms. In one embodiment, the activated gas mixture comprises from about 6% to about 20% nitrogen atoms. In one embodiment, the activated gas mixture comprises from about 10% to about 20% oxygen atoms. In one embodiment, the activated gas mixture comprises about 10% to about 20% carbon atoms.

In another embodiment of the invention, the activated gas mixture comprises from about 50% to about 60% fluorine atoms, from about 8% to about 15% nitrogen atoms, from about 10% to about 20% oxygen atoms, and from about 10% to about 20% carbon atoms.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

### EXAMPLES

The concepts described herein will be further described in the following examples, which do not limit the scope of the invention described in the claims.

The feed gases (e.g. O₂, fluorocarbon, NF₃ and nitrogen gas) were introduced into the remote plasma source and passed through the toroidal discharge where they were discharged by the 400 kHz radio-frequency power to form an activated gas mixture. The oxygen is manufactured by Airgas with 99.999% purity. The fluorocarbon in the examples is Zyron® 116 N5 manufactured by DuPont with a minimum 99.9 vol. % of hexafluoroethane. The NF₃ gas is manufactured by DuPont with 99.999% purity. Nitrogen and Argon are supplied by Airgas. Typically, Ar gas is used to ignite the plasmas, after which time flows for the feed gases were initiated, after Ar flow was halted. The activated gas mixture then is passed through an aluminum water-cooled heat exchanger to reduce the thermal loading of the aluminum process chamber. The surface deposits covered wafer was placed on a temperature controlled mounting in the process chamber. See also B. Bai and H Sawin, Journal of Vacuum Science & Technology A 22 (5), 2014 (2004), which is herein incorporated by reference. The etching rate of surface deposits by the activated gas is measured by interferometry equipment in the process chamber. N₂ gas is added at the entrance of the exhaustion pump both to dilute the products to a proper concentration for FTIR measurement and to reduce the hang-up of products in the pump. FTIR was used to measure the concentration of species in the pump exhaust.

### EXAMPLE 1

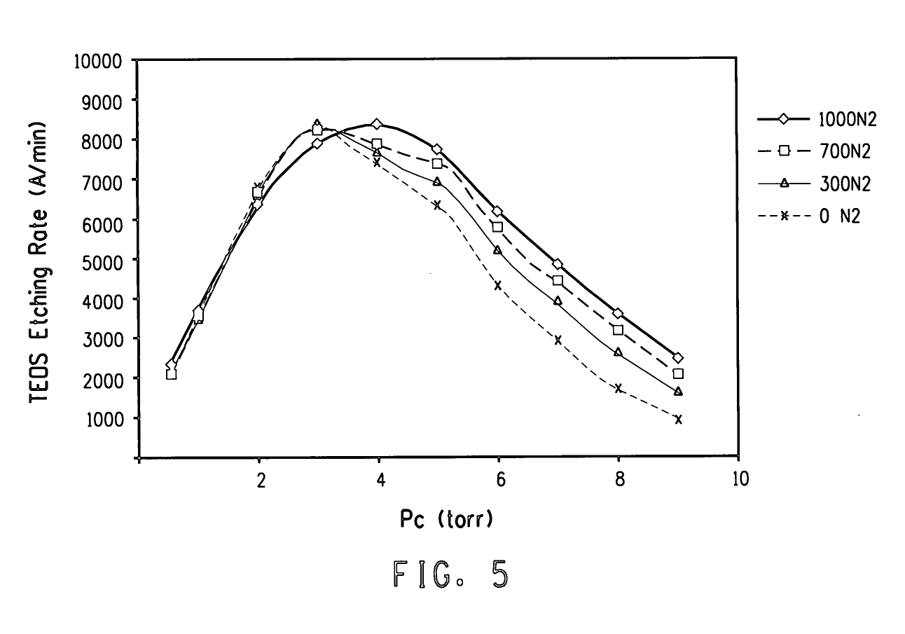

This example illustrates the effect of nitrogen addition on silicon dioxide etch rate and power consumption using a mixture of NF₃, oxygen, and C₂F₆. Individual gas flow rates were as indicated, as measured in sccm. Remote chamber pressures were varied from 0.5 torr to 9 torr. The activated gas then entered the process chamber and etched the silicon dioxide surface deposits on the mounting with the temperature controlled at 250° C. Results are illustrated in FIG. 5.

### EXAMPLE 2

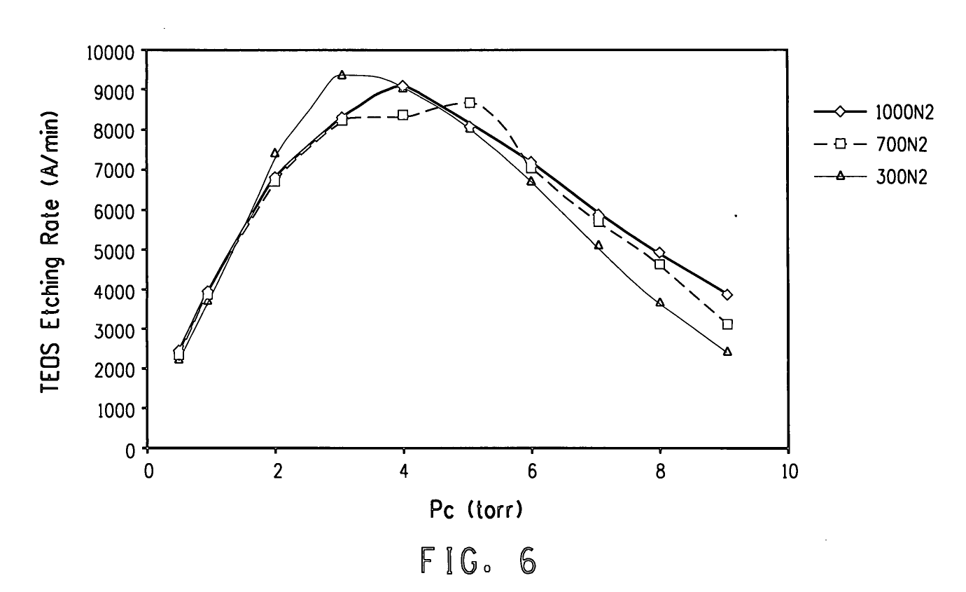

The procedure of example 1 is followed, with the flow rate NF₃ set at 650 sccm. Results are illustrated in FIG. 6.

### EXAMPLE 3

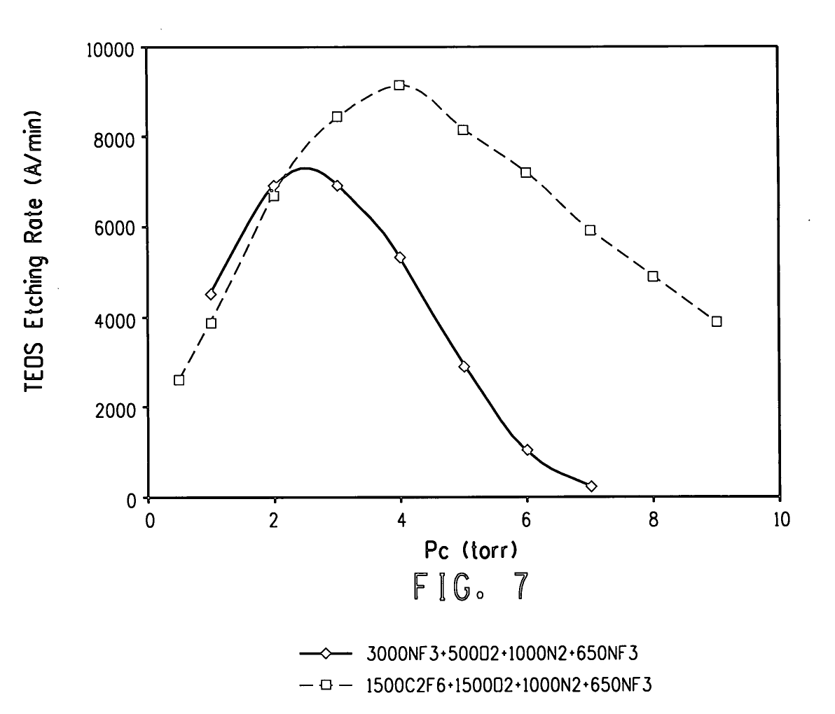

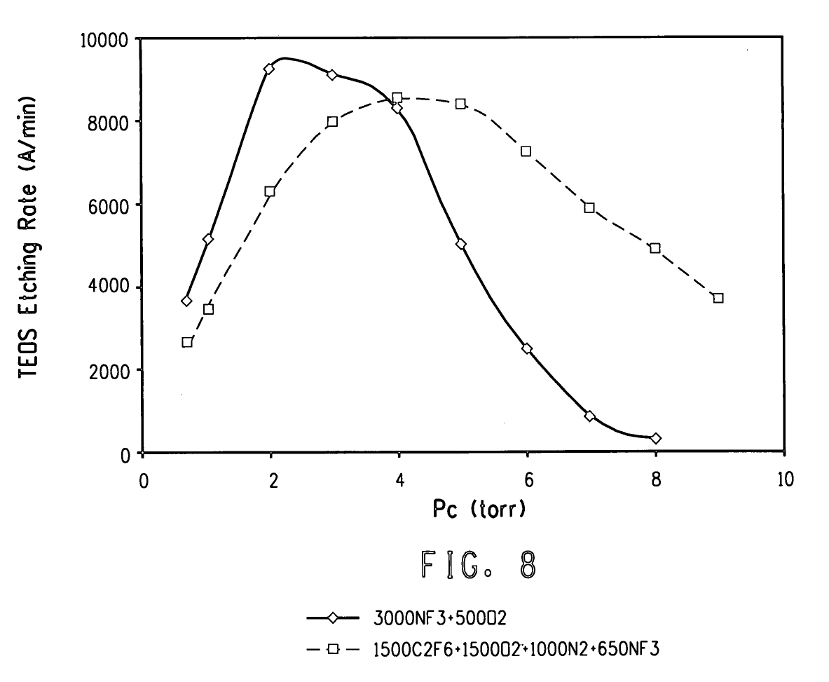

This example illustrates the effect on etch rate and power consumption with and without a flow restricting device on the procedure of example 1 Gas flows and compositions were as indicated. Results are illustrated in FIGS. 7 and 8.

### EXAMPLE 4

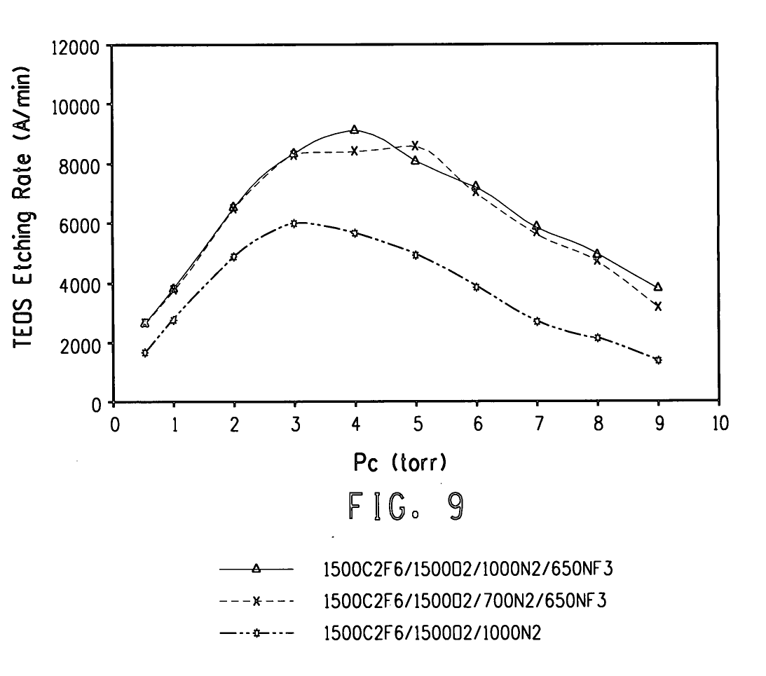

Using the procedure of example 1, this example illustrates etch rates and power consumption with and without NF₃ using two different nitrogen flow rates. Results are illustrated in FIG. 9.

### EXAMPLE 5

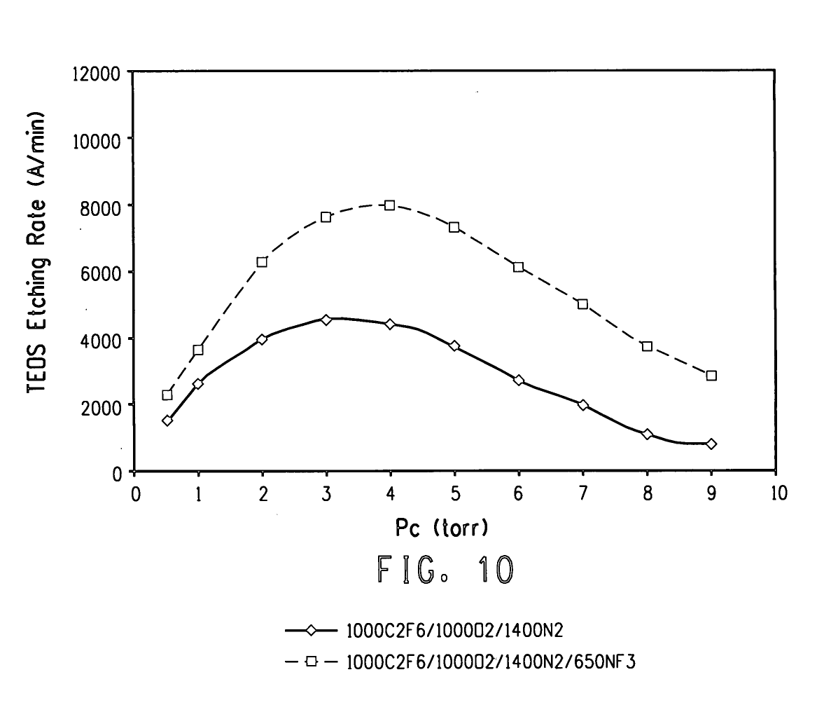

This example illustrates the effect of NF₃ on etch rate and power consumption similar to Example 4, at a higher nitrogen flow rate. Results are illustrated in FIG. 10.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. A deposition apparatus assembly comprising:
(a) a deposition chamber,
(b) a remote chamber outside the deposition chamber for producing reactive species from a precursor gas mixture,
(c) an activation source adapted to deliver energy into said remote chamber,
(d) a conduit for flowing the reactive species from said remote chamber to said deposition chamber; and
(e) a flow restricting device interposed between said remote chamber and said conduit wherein said flow restricting device is cooled by an external cooling source.

2. An apparatus as in claim 1 wherein the flow restricting device is a water-cooled orifice.

3. An apparatus as in claim 1 wherein the activation source delivers a power of at least 12 kW.

4. An apparatus as in claim 2 wherein the diameter of the orifice is from about 0.25 inches to about 0.45 inches.

5. An activated gas mixture comprising:
(a) from about 50% to about 74% fluorine atoms,
(b) from about 6% to about 20% nitrogen atoms,
(c) from about 10% to about 20% oxygen atoms, and
(d) from about 10% to about 20% carbon atoms.

6. An activated gas mixture as in claim 4 wherein said gas mixture comprises:
(a) From about 50% to about 60% fluorine atoms,
(b) From about 8% to about 15% nitrogen atoms,
(c) From about 10% to about 20% oxygen atoms, and
(d) from 10% to about 20% carbon atoms.

7. A process for etching and removing surface deposits on the interior surfaces of a CVD apparatus, comprising:
(a) activating in a remote chamber a gas mixture comprising an oxygen source, nitrogen trifluoride, a fluorocarbon, and nitrogen, using a power of at least 12 kW,
(b) allowing said activated gas mixture to flow through a water-cooled flow restricting device, a conduit and into a process chamber, and thereafter
(c) contacting said activated gas mixture with the surface deposits and thereby removing at least some of the said deposits.

8. The process of claim 6, wherein the remote chamber is maintained at a higher pressure than the deposition chamber by said water-cooled flow restricting device.

9. The process of claim 6 wherein the fluorocarbon is a perfluorocarbon

10. The process of claim 6 wherein the fluorocarbon is hexafluoroethane.

11. The process of claim 6 wherein the oxygen source is molecular oxygen.

12. A process for etching and removing surface deposits on the interior surfaces of a CVD apparatus, comprising:
(a) forming an activated gas mixture comprising, from about 50% to about 74% fluorine atoms, from about 6% to about 20% nitrogen atoms, from about 10% to about 20% oxygen atoms, and from about 10% to about 20% carbon atoms, in a remote chamber using a power of at least 12 kW,
(b) allowing said activated gas mixture to flow through a water-cooled flow restricting device, a conduit and into a process chamber, and thereafter
(c) contacting said activated gas mixture with the surface deposits and thereby removing at least some of the said deposits.

13. The process of claim 11 wherein the remote chamber is maintained at a higher pressure than the deposition chamber by said water-cooled flow restricting device.
